(19) United States
(12) Patent Application Publication
(10) Pub. No.: US 2023/0243896 A1
(43) Pub. Date: Aug. 3, 2023

(54) METHOD AND SYSTEM FOR DETERMINING A CHARACTERISTIC VARIABLE

(71) Applicant: Maschinenfabrik Reinhausen GmbH, Regensburg (DE)

(72) Inventors: Irina Lupandina, Vienna (AT); Michael Schrammel, Vienna (AT)

(21) Appl. No.: 18/003,349

(22) PCT Filed: Jun. 11, 2021
(86) PCT No.: PCT/EP2021/065797

§ 371 Date: Dec. 27, 2022

(30) Foreign Application Priority Data
Jul. 14, 2020 (DE) 10 2020 118 490.5

(51) Int. Cl. G01R 31/62

(52) U.S. Cl. CPC G01R 31/62

(57) ABSTRACT

A characteristic variable represents a thermal load on an electrical device. A first mathematical model determines the characteristic variable for a determination time based on an ambient temperature of the electrical device and a value of a thermal operating parameter of the electrical device. The first mathematical model describes a dependency of thermal operating parameters of the electrical device at a calculation time based on the ambient temperature of the electrical device and on an electrical load factor. The characteristic variable is determined for the determination time as the equivalent electrical load factor of the electrical device, for which the first mathematical model, taking into account the ambient temperature at the determination time, predicts a value of the thermal operating parameter of the electrical device determined for the determination time.

### CROSS REFERENCE TO RELATED APPLICATIONS

This application is a U.S. National Phase application under 35 U.S.C. § 371 of International Application No. PCT/EP2021/065797, filed on Jun. 11, 2021, and claims benefit to German Patent Application No. DE 10 2020 118 490.5 A1, filed on Jul. 14, 2020. The International Application was published in German on Jan. 20, 2022 as WO 2022/012828 A1 under PCT Article 21(2).

### FIELD

The present disclosure relates to a method for determining a characteristic variable which can be used to represent a thermal load on an electrical device for a determination time. Furthermore, the present disclosure relates to a method for calculating grid safety in an electrical grid comprising a plurality of electrical devices, relates to a method for managing the operation of an electrical device, relates to a system for determining a characteristic variable, relates to a system for calculating grid safety in an electrical grid comprising a plurality of electrical devices, and relates to a system for managing the operation of an electrical device.

### BACKGROUND

The reliability of electrical devices of electrical grids as well as the resilience and overload capacity depend crucially on the history of the devices and the temperatures to which the electrical devices were exposed. For example, the aging of the solid insulation and the dielectric strength of the insulation of transformers depend significantly on the temperatures at which the transformer was operated. For reliable operation of the electrical devices, it is therefore necessary to determine relevant temperatures of devices and to use these temperatures to determine their thermal load factor or their thermal state.

For example, the thermal state of a power transformer is described by the top oil temperature or hot spot temperature. If the temperatures exceed certain limit values over certain periods of time, the electrical devices ages disproportionately quickly, which can impair the grid safety and stability.

The relevant temperatures can be measured continuously, such as the top oil temperature. Alternatively, it is also possible to predict temperatures from other measured values using dynamic models. For example, the hot spot temperature of a transformer can be predicted from the measured top oil temperature, the measured load factor of the transformer and the ambient temperature of the transformer.

To ensure that the temperatures do not exceed any limit values during operation of the electrical devices, maximum load factors are assumed when planning the load factor of the electrical devices, under which loads the temperatures do not exceed any limit values in the assumed state of equilibrium. If these maximum load factors are not exceeded when managing the operation of the electrical devices, the critical temperature limits will not be exceeded either and thus the electrical devices will not age prematurely. The maximum permissible load factors are also taken into account when calculating the grid safety, for example by assuming the difference between the actual load factor of the electrical device and the maximum permissible load factor of the device as the reserve load factor, which is still available, for example, in the event of unexpected high demand or failure of other electrical devices.

Based on this background, the inventors have determined that the consideration of the thermal state of electrical devices when controlling electrical grids, calculating the grid safety and controlling the operation of electrical components should be simplified.

### SUMMARY

In an embodiment, the present disclosure provides a method that determines a characteristic variable for representing a thermal load on an electrical device. The method includes determining, by a first mathematical model, the characteristic variable for a determination time based on an ambient temperature of the electrical device at the determination time and a determined value of a thermal operating parameter of the electrical device at the determination time. The first mathematical model describes a dependency of thermal operating parameters of the electrical device at a calculation time based on the ambient temperature of the electrical device at the calculation time, and on an electrical load factor of the device at the calculation time. The characteristic variable is determined for the determination time as the equivalent electrical load factor of the electrical device, for which the first mathematical model, taking into account the ambient temperature at the determination time, predicts a value of the thermal operating parameter of the electrical device determined for the determination time.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a schematic illustration of an exemplary embodiment of part of an electrical grid having a plurality of electrical devices;

FIG. 2 shows a schematic illustration of an exemplary embodiment of a data processing apparatus; and

FIG. 3 shows a schematic illustration of an exemplary embodiment of a method for determining a characteristic variable for representing a thermal load on an electrical device.

### DETAILED DESCRIPTION

In a first aspect, a problem of the present disclosure is solved by a method for determining a characteristic variable for representing a thermal load on an electrical device for a determination time based on an ambient temperature of the electrical device at the determination time and a determined value of a thermal operating parameter of the device at the determination time by means of a first mathematical model that describes a dependency of the thermal operating parameter of the device at a calculation time on the ambient temperature of the electrical device at the calculation time and the electrical load factor of the device at the calculation time. The characteristic variable for the determination time is determined as the equivalent electrical load factor of the electrical device, for which the first mathematical model, taking into account the ambient temperature at the determination time, predicts the value of the thermal operating parameter of the electrical device determined for the determination time.

As part of the method, a characteristic variable is determined that represents the thermal load on the device at a determination time and that can be used intuitively, for example when calculating the grid safety or when managing the operation of the device, and can be easily integrated into existing processes. Examples of electrical devices in power grids are, for example, transformers, overhead lines, underground cables and circuit breakers.

To this end, the value of a thermal operating parameter for the determination time, for example the hot spot temperature or the top oil temperature of a transformer, is first of all determined. Preferred embodiments relate to various possible ways of determining the thermal operating parameter, the suitability of which depends, among other things, on the selected time for which the characteristic variable is intended to be determined. An ambient temperature of the electrical device at the determination time is also determined. The ambient temperature can be measured, for example, or taken from prediction data. Alternatively, it is also possible to use a predetermined value for the ambient temperature at the determination time. For example, the ambient temperature at the determination time may be set to an average maximum temperature of the installation site of the device. In this case, it is particularly preferred if the ambient temperature for the determination time is set to a value that was used to calculate a rated current of the electrical device. The value of the thermal operating parameter and the ambient temperature at the determination time as well as possibly other input variables form the basis for determining the characteristic variable using the first mathematical model.

This mathematical model describes the thermal operating parameter that has already been determined, for example the hot spot temperature of a transformer, at a specific time as a function of the ambient temperature of the electrical device at the specific time and the electrical load factor of the electrical device at the specific time. If necessary, other input variables can also be used. The first mathematical model is therefore a static model which can usually be used to calculate a further operating parameter from the plurality of input operating parameters of the electrical device (here: the ambient temperature and the electrical load factor) without dynamic effects such as changing ambient temperatures or load factors being taken into account. The first mathematical model thus represents a state of equilibrium. Examples of suitable mathematical models that can be used as the first mathematical model for a transformer are the mathematical models from IEC 60076-7, which describe the hot spot temperature and the top oil temperature of a transformer in equilibrium.

The first mathematical model is used to determine the electrical load factor of the device, for which the first mathematical model, taking into account the known ambient temperature, predicts the previously determined thermal operating parameter. The missing input variable is thus determined from a known input variable and the known output variable. The electrical load factor determined in this way, for which the first mathematical model would predict the previously determined electrical operating parameter independently of the actual electrical load factor of the electrical device, taking into account at least the ambient temperature, is referred to as the equivalent electrical load factor.

The characteristic variable or equivalent electrical load factor can be used in an advantageous manner, for example when controlling the electrical device or in grid safety calculations at the determination time, instead of the actual electrical load factor. The equivalent electrical load factor represents the determined value of the thermal operating parameter and the ambient temperatures. In this way, it is advantageously taken into account that, for example, at lower ambient temperatures, higher load factors of the electrical devices are possible without the limit temperatures being exceeded.

In contrast to conventional calculations, dynamic effects are also taken into account by taking the characteristic variable into account. The electrical device thus reacts sluggishly after every change in the ambient temperature or the load factor of the electrical device and does not change immediately from one steady state to the other. The thermal operating parameter thus does not change abruptly from one value to the other in the case of an exemplary change in the load factor of the device, but rather continuously and with a delay. For example, when the load factor increases, the thermal operating parameter follows only slowly, with the result that, for example, the device can be utilized to a significantly higher extent in the short term without critical temperatures being exceeded.

In one preferred embodiment, the determined thermal operating parameter of the electrical device is determined at the determination time by means of a second mathematical model that describes a dependency of the thermal operating parameter of the electrical device on a progression of an ambient temperature of the electrical device, a progression of an electrical load factor of the device and a starting value for the thermal operating parameter. In this case, a value for the thermal operating parameter at a starting time is used as the starting value for the thermal operating parameter. The value for the thermal operating parameter at the starting time was preferably measured on the electrical device. The progression of the ambient temperature describes the progression of the ambient temperature of the device between the starting time and the determination time, and the progression of the electrical load factor of the device describes the progression of the electrical load factor of the device between the starting time and the determination time.

In a preferred embodiment, the thermal operating parameter is calculated using a second mathematical model which, in contrast to the first mathematical model, does not describe a steady state. Rather, the second mathematical model takes into account the progression of the ambient temperature and the progression of the load factor of the device starting from a starting time at which the thermal operating parameter was known, for example by direct measurement or by calculation from other directly measured values. Examples of models that can be used as the second mathematical model for a transformer include the dynamic model from IEC 60076-7, which can be used to calculate the hot spot temperature and the top oil temperature of a transformer.

For example, the characteristic variable for a future time can be calculated in an advantageous manner from a single measurement of the thermal operating parameter. However, it is also conceivable to determine the characteristic variable for a determination time that is in the past relative to the starting time, in order to be able to estimate, for example, load factors that, according to the stationary model led to overloading and thus premature aging of the electrical device, have also actually led to overloading.

It is also preferred in this case if, as part of the method, a progression of the characteristic variable is determined for an evaluation period comprising a plurality of evaluation times by determining, for each evaluation time as the determination time, a determined value for the thermal operating parameter of the electrical device using the second mathematical model and determining, on the basis of the value thus determined for the thermal operating parameter of the electrical device, the characteristic variable for the respective evaluation time as the determination time using the first mathematical model.

It is also preferred to determine the progression of the characteristic variable as the future expected progression of the characteristic variable, starting from a current time as the starting time, over the evaluation period. A prediction of a progression of the ambient temperature of the device from the starting time over the evaluation period is used in this case as the progression of the ambient temperature, and a prediction of a progression of the electrical load factor of the device from the starting time over the evaluation period is used as the progression of the electrical load factor of the device.

In the preferred embodiment, the characteristic variable is therefore not only determined for a single determination time, but for an evaluation period. This is particularly advantageous when calculating the future grid safety or when the operation of the device is planned for a future period, since the equivalent thermal load factor and thus dynamic effects in conventional systems can be taken into account over the entire period.

In a further preferred embodiment of the method, the determined value of the thermal operating parameter of the device is measured on the device or is calculated from one or more measured operating parameters and/or a measured ambient temperature of the device and/or a measured load factor of the device. In other words, the determined value of the thermal operating parameter can be measured directly in the preferred embodiment. Alternatively, the value can be calculated using other measured values. Examples of measured values from which the thermal operating parameter can be determined are the ambient temperature of the device, other measured thermal operating parameters and a measured load factor.

An equivalent electrical load factor of the electrical device, for which a difference between the thermal operating parameter determined by means of the first mathematical model for the determination time and the thermal operating parameter of the electrical device at the determination time falls below a predetermined limit value, is preferably determined for a determination time as the characteristic variable for representing the thermal load on the electrical device, wherein an optimization algorithm, and preferably a gradient-based optimization algorithm such as Newton's method, is used to reduce the difference.

In a first mathematical model that cannot be resolved analytically for the electrical load factor, the equivalent thermal load factor is determined using an iterative approximation method.

It is also preferred to determine, for a determination time, a limit characteristic variable of the electrical device as that electrical load factor for which the first mathematical model, taking into account the ambient temperature of the electrical device at the determination time, predicts a value for the thermal operating parameter of the electrical device which corresponds to a limit value of the thermal operating parameter that must not be contravened by the operating parameter. The limit value preferably depends on an operating mode of the electrical device.

In the preferred embodiment, in addition to the equivalent thermal load factor, limit characteristic variables are additionally determined by using the first mathematical model to calculate which load factor, according to the first mathematical model, would result in a permissible limit value for the thermal operating parameter being reached at the ambient temperature present at the determination time. In this way, when managing the operation of the electrical device, it can be taken into account that low ambient temperatures permit higher load factors of the device until the thermal operating parameter exceeds a limit value.

More preferably, a difference between the limit characteristic variable determined for a determination time and the characteristic variable determined for the determination time is calculated as the reserve characteristic variable. The reserve characteristic variable can be advantageously taken into account in grid safety calculations, since it indicates the additional load that can be absorbed by a device at the respective determination time without the thermal operating parameter exceeding a limit value and accelerated aging of the device occurring.

In one preferred embodiment, different mathematical models are used as the second mathematical model depending on a progression of an electrical load factor of the electrical device. In this way, different mathematical models can be used in an advantageous manner for different load profiles, since, depending on the load profile, different models can be particularly suitable for describing the development of the thermal operating parameter.

In a further aspect, a problem of the present disclosure is solved by a method for calculating grid safety in an electrical grid comprising a plurality of electrical devices based on an expected progression of a load factor of the plurality of electrical devices, wherein, for at least one electrical device of the plurality of electrical devices, an expected progression of the characteristic variable for the at least one electrical device, which is determined by means of a corresponding embodiment of the method described above, is used as the expected progression of the load factor of the electrical device.

The advantages of the method for calculating grid safety correspond to the advantages of the method used to determine the characteristic variable for the at least one electrical device.

In a further aspect, a problem of the preset disclosure is solved by a method for managing the operation of an electrical device, in which an electrical load factor of the electrical device at a determination time is adjusted taking into account the characteristic variable determined for the determination time by means of a corresponding embodiment of the method described above.

The advantages of the method for managing the operation of an electrical device correspond to the advantages of the method used to determine the characteristic variable for the at least one electrical device.

In a further aspect, a problem of the present disclosure is solved by a system for determining a characteristic variable for representing a thermal load on an electrical device for a determination time, wherein the system comprises a data processing apparatus configured to carry out a method a corresponding method according to one of the preceding embodiments.

In a further aspect, a problem of the present disclosure is solved by a system for calculating grid safety in an electrical grid comprising a plurality of electrical devices, wherein the system comprises a data processing device configured to carry out a corresponding method according to one of the preceding embodiments.

In a further aspect, a problem of the present disclosure is solved by a system for managing the operation of an electrical device, wherein the system comprises a data processing unit configured to carry out a corresponding method according to one of the preceding embodiments.

The advantages of the various embodiments of the systems correspond in each case to the advantages of the methods that the data processing units of the systems are configured to carry out in each case. In addition, the configurations of the method presented in the context of the description of the methods can also be applied to the respective system.

A plurality of exemplary embodiments of a method for determining a characteristic variable and of a system in which the corresponding methods can be carried out are described in more detail below with reference to the drawings.

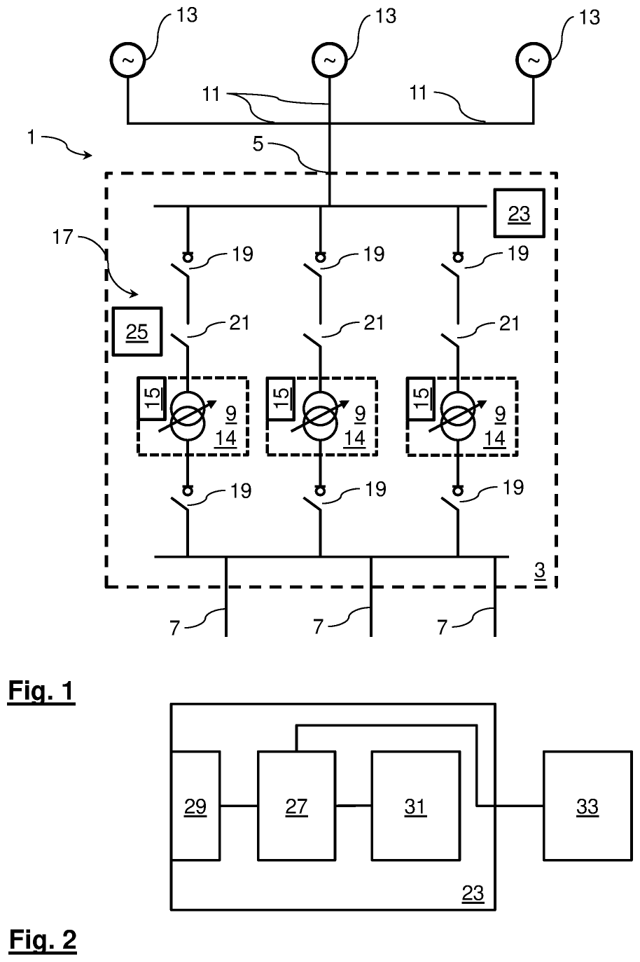

FIG. 1 first shows an embodiment of part of an electrical grid or power grid in the form of a substation 3 and a plurality of generators 13. The substation 3 comprises a supply input 5, a plurality of outgoing circuits 7 and a plurality of electrical devices or components 9. Only three outgoing circuits 7 and only three electrical components 9 are illustrated in FIG. 1, but the substation 3 can comprise more or fewer outgoing circuits and electrical devices.

The supply input 5 is connected via overhead lines 11, which are likewise electrical devices, to the three generators 13 which may be wind energy installations, for example. The substation 3 is connected, via further lines which are connected to the outgoing circuits 7, to loads or consumers. The electrical grid 1 can comprise additional substations, additional generators and additional consumers.

The electrical devices 9 of the power grid 1 which are illustrated in the exemplary embodiment are transformers 14. A monitoring unit 15 is arranged on each transformer 14 and determines and manages operating parameters and key figures of the transformer 14. For example, the monitoring unit 15 uses a sensor to determine a top oil temperature of the transformer 14 as a thermal operating parameter and uses this to determine a hot spot temperature in turns of coils of the transformer 14 using a suitable mathematical model and further operating parameters and key figures of the transformer 14. The monitoring unit 15 also records the current flowing through the transformer 14. Furthermore, characteristic data that do not change over time, such as nominal power and year of manufacture of the transformer, and historical data, for example DGA analyses, commissioning tests and results of visual inspections, are kept in the monitoring unit 15.

Limit values which must not be exceeded during operation are defined for each electrical device 9. These limit values can be stored in the monitoring units. For example, limit values for the top oil temperature and the hot spot temperature can be stored.

The substation 3 also comprises a plurality of circuit breakers 19 and disconnecting switches 21, collectively referred to as switches 19, 21, which together form a switching arrangement 17. The switches 19, 21 are also electrical devices.

Finally, the substation 3, and thus the power grid 1, comprises a central data processing device, data processing unit or data processing apparatus (data processor) 23 which is connected to the monitoring units 15 and also to a controller 25 of the substation 3, which controls the positions of the switches 19, 21, in particular. The central data processing 23 is also connected to external data sources, which will be discussed in yet more detail below.

FIG. 2 schematically shows the structure of an exemplary data processing apparatus 23, like that shown in FIG. 1. This comprises a central processing unit or CPU 27, a communication unit 29 and a memory 31. Furthermore, FIG. 2 shows a user interface 33, for example a screen and one or more input devices, via which a user can interact with the central data processing unit 23 and via which results of calculations can be displayed to the user. The user interface 33 is not necessarily part of the central data processing unit 23. Via the communication unit 29, the central data processing unit 23 can communicate, inter alia, with the controller 25, the monitoring units 15 and other data sources, i.e. can receive and transmit data.

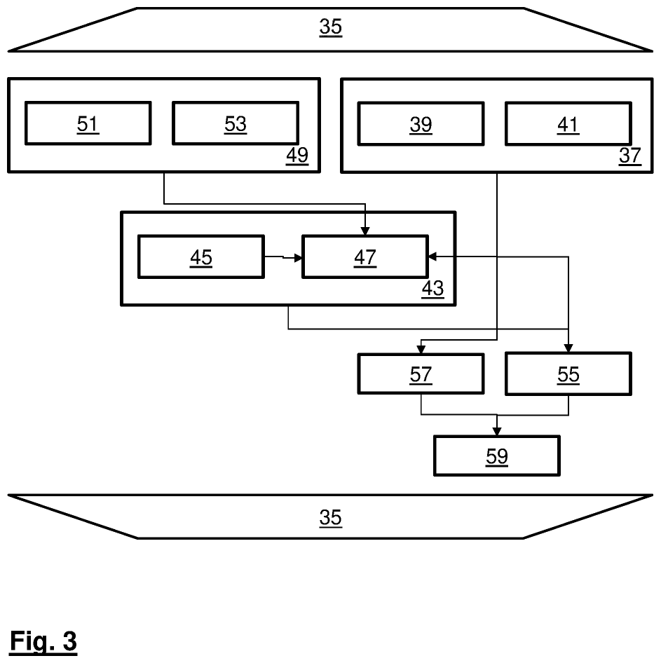

Finally, FIG. 3 shows a flowchart of an exemplary embodiment of a method which is used to determine a key figure for an electrical device 9, 11, 19, 21, which key figure represents a thermal load on the device 9, 11, 19, 21. In the exemplary embodiment illustrated, the device 9 is a transformer 14.

The method shown in FIG. 3 is designed to determine the key figure for a period of 24 hours or 48 hours, for example. This period is referred to as the evaluation or prediction period, over which the progression of the characteristic variable is determined. The evaluation period usually comprises a multiplicity of evaluation times which can be distributed evenly over the evaluation period in 15-minute intervals, for example. However, the method can also be used to determine the key figure only for a single time, for example by restricting the evaluation period to this one time.

As indicated by the two trapezoids 35, the method steps presented below are carried out for all evaluation times of the prediction period. The method steps can be repeated, i.e. executed sequentially, for each evaluation time. However, it is also possible to execute some or all of the method steps in a parallel manner. The specific sequence of the steps and the extent to which individual steps have to be repeated for each evaluation time, processed in a parallel manner for all evaluation times or possibly carried out only once for all evaluation times are known to a person skilled in the art from his general specialist knowledge.

The performance of the method is described below as if all method steps are repeated for each evaluation time. The evaluation time for which the method is currently being carried out is referred to below as the determination time.

In the present exemplary embodiment, an ambient temperature of the transformer 14 is first of all determined in a first method step 37. If the determination time is the current time, the ambient temperature can be measured in an ambient temperature measurement 39 by means of a temperature sensor. Alternatively, the ambient temperature can also be read from a database which holds ambient temperature data (second step 41). This may be necessary in particular if the determination time is in the future or in the past.

Ambient temperatures for the future and also current temperatures can be taken from prediction data or weather reports, for example, which are provided by external service providers. Ambient temperatures for determination times in the past can be taken from a database, for example, which is filled with its own measured values or can also be made available by external service providers.

The ambient temperatures can also be made available to the method by a monitoring unit 15 arranged on the transformer 14.

In a third step 43, a thermal operating parameter of the transformer 14 is determined or ascertained at the determination time. In the present exemplary embodiment, the thermal operating parameter is the top oil temperature or the hot spot temperature of the transformer. The thermal operating parameter can be measured, for example, in an operating parameter measurement 45, in particular if the determination time is the current time and the operating parameter, such as the top oil temperature, can be measured directly. If the hot spot temperature, which can be measured directly only with great effort, is used as the thermal operating parameter, the thermal operating parameter can also alternatively be derived from other measured operating parameters. The hot spot temperature can be calculated, for example, from the ambient temperature, the measured top oil temperature and other measured values, such as the load factor of the transformer 14.

Alternatively, the thermal operating parameter can also be calculated in an operating parameter calculation 47 using a mathematical model. This can mean, in particular for determination times in the future, that the value of the thermal operating parameter is calculated using a second mathematical model. The second mathematical model dynamically describes the development of the thermal operating parameter, starting from a starting time for which the thermal operating parameter is known, taking into account the development of the ambient temperature and the load factor of the transformer 14. Different second mathematical models can be used depending on the progression of the load factor of the transformer 14. For example, one second mathematical model can describe sudden load changes particularly well, and another second model can describe uniform load changes over long periods.

If the determination time is in the past, the thermal operating parameter can also be calculated using the operating parameter calculation 47 or can be taken from a database. Finally, the thermal operating parameter can also be determined by virtue of a monitoring unit 15 arranged on the transformer 14 making this available on request of the method.

The electrical load factor of the electrical device 9, 11, 19, 21 required in the operating parameter calculation 47 is determined in a fourth step 49. If the current electrical load factor is required, it can be determined in a load factor measurement 51. Otherwise, the electrical load factor can be determined in a database query 53, in which either recorded measured values for determination times in the past or predicted electrical load factors for the future are queried. In particular, predicted measured values can also be queried from external data sources.

The electrical load factor can also be made available to the method by a monitoring unit 15 which is arranged on the transformer 14 and undertakes the steps described above.

Finally, in a fifth step 55, the key figure for the thermal load factor is determined from the ambient temperature obtained in the first step 37 and the thermal operating parameter obtained in the third step, the hot spot temperature or the top oil temperature of the transformer 14. For this purpose, a first mathematical model, which describes the dependency of the thermal operating parameter in equilibrium, i.e. in a steady state, on the ambient temperature and the electrical load factor, is used to determine that equivalent electrical load factor for which the first mathematical model predicts the previously determined thermal operating parameter as a function of the ambient temperature.

In particular, an optimization algorithm, such as Newton's method, in which a solution for the mathematical model is iteratively sought, can to determine the equivalent electrical load factor. Like all previous method steps, this method step can also be carried out in a monitoring unit 15.

In a sixth step 57, an equivalent electrical limit load factor is determined as a limit characteristic variable from the ambient temperature obtained in the first step 37 and one or more limit values known for the thermal operating parameter by determining the electrical load factor for which the first mathematical model predicts the limit value for the thermal operating parameter as a function of the ambient temperature determined for the determination time.

Finally, in a final seventh step 59, the difference between the limit characteristic variable and the characteristic variable is determined as the reserve characteristic variable, which indicates, for the determination time, the extent to which the electrical load factor of the transformer 14 can be increased without the transformer 14 being overloaded.

If the above steps are carried out for a multiplicity of successive determination times, i.e. over longer evaluation periods, the determined characteristic variables, limit characteristic variables and reserve characteristic variable can be combined to form profiles that may be particularly helpful when assessing past events or for planning the future control of the electrical grid 1 and the respective electrical resource. In this case, the method steps described so far are used as part of a method for controlling the electrical device or a method for calculating grid safety, in which the calculations are preferably carried out for a multiplicity of electrical devices.

As already mentioned, the method described for calculating the characteristic variable can be carried out entirely on a monitoring unit 15 which in this case is equipped with a processor or data processing device and forms a system for determining a key figure. Alternatively, a distributed calculation of the key figures is also conceivable, in which a portion of the method steps is carried out by a monitoring unit 15 and another portion is carried out by a central data processing device 23 which can also be part of a cloud.

The same also applies to the corresponding methods for calculating grid safety and for managing the operation of an electrical device and to the corresponding systems in which the respective data processing apparatuses can also be formed by the monitoring units, a central data processing unit or a cloud or mixed forms of these.

The exemplary embodiments of the methods and systems make it possible for the thermal load factor of electrical devices to be taken into account in an intuitive manner and, in particular, allow the new methods to be easily integrated into existing systems that only take into account the electrical load factor of the electrical devices without these having to be changed.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS

1 Power grid, electrical grid
3 Substation
5 Supply input
7 Outgoing circuit
9 Electrical devices, components
11 Overhead lines, electrical devices
13 Generator
14 Transformer
15 Monitoring unit
17 Switching arrangement
19 Circuit breakers, electrical devices
21 Disconnecting switches, electrical devices
23 Central data processing apparatus, device, unit
25 Controller of the substation
27 CPU
29 Communication unit
31 Memory
33 User interface
35 Trapezoids
37 First step
39 Ambient temperature measurement
41 Second step
43 Third step
45 Operating parameter measurement
47 Operating parameter calculation
49 Fourth step
51 Load factor measurement
53 Database query
55 Fifth step
57 Sixth step
59 Seventh step

1. A method for determining a characteristic variable for representing a thermal load on an electrical device, the method comprising:
determining, by a first mathematical model, the characteristic variable for a determination time based on an ambient temperature of the electrical device at the determination time and a determined value of a thermal operating parameter of the electrical device at the determination time, the first mathematical model describing a dependency of thermal operating parameters of the electrical device, comprising the thermal operating parameter, at a calculation time based on the ambient temperature of the electrical device at the calculation time and on an electrical load factor of the electrical device at the calculation time,
wherein the characteristic variable is determined for the determination time as the equivalent electrical load factor of the electrical device, for which the first mathematical model, taking into account the ambient temperature at the determination time, predicts a value of the thermal operating parameter of the electrical device determined for the determination time.

2. The method as claimed in claim 1, the method further comprising determining by a second mathematical model, the thermal operating parameter of the electrical device at the determination time, the second mathematical model describing a dependency of the thermal operating parameter of the electrical device based on a progression of the ambient temperature of the electrical device, a progression of the electrical load factor of the electrical device, and a starting value for the thermal operating parameter,
wherein a value for the thermal operating parameter at a starting time is used as the starting value for the thermal operating parameter,
wherein the value for the thermal operating parameter at the starting time is measured on the electrical device,
wherein the progression of the ambient temperature describes the progression of the ambient temperature of the electrical device between the starting time and the determination time, and
wherein the progression of the electrical load factor of the electrical device describes the progression of the electrical load factor of the electrical device between the starting time and the determination time.

3. The method as claimed in claim 2, the method further comprising determining a progression of the characteristic variable for an evaluation period comprising a plurality of evaluation times by determining, for each evaluation time as the determination time, a determined value for the thermal operating parameter of the electrical device using the second mathematical model and determining, based on the value thus determined for the thermal operating parameter of the electrical device, the characteristic variable for the respective evaluation time as the determination time using the first mathematical model.

4. The method as claimed in claim 3, wherein the progression of the characteristic variable is determined as the future expected progression of the characteristic variable, starting from a current time as the starting time, over the evaluation period,
wherein a prediction of the progression of the ambient temperature of the electrical device from the starting time over the evaluation period is used as the progression of the ambient temperature, and
wherein a prediction of the progression of the electrical load factor of the electrical device from the starting time over the evaluation period is used as the progression of the electrical load factor of the device.

5. The method as claimed in claim 1, wherein the determined value of the thermal operating parameter of the electrical device is measured on the device, or
wherein the determined value of the thermal operating parameter of the electrical device is calculated from one or more measured operating parameters, or a measured ambient temperature of the electrical device, or a measured load factor of the electrical device.

6. The method as claimed in claim 1, wherein an equivalent electrical load factor of the electrical device, for which a difference between the thermal operating parameter determined by the first mathematical model for the determination time and the thermal operating parameter of the electrical device at the determination time falls below a predetermined limit value, is determined for a determination time as the characteristic variable for representing the thermal load on the electrical device, wherein an optimization algorithm is used to reduce the difference.

7. The method as claimed in claim 1, wherein, for the determination time, a limit characteristic variable of the electrical device is determined as that electrical load factor for which the first mathematical model, taking into account the ambient temperature of the electrical device at the determination time, predicts a value for the thermal operating parameter of the electrical device, which corresponds to a limit value of the thermal operating parameter that must not be contravened by the operating parameter,
wherein the limit value depends on an operating mode of the electrical device.

8. The method as claimed in claim 6, wherein a difference between the limit characteristic variable determined for the determination time and the characteristic variable determined for the determination time is calculated as the reserve characteristic variable.

9. The method as claimed in claim 1, wherein different mathematical models are used as the second mathematical model depending on a progression of an electrical load factor of the electrical device.

10. A method for calculating grid safety in an electrical grid comprising a plurality of electrical devices, comprising the electrical device, based on an expected progression of a load factor of the plurality of electrical devices, wherein, for at least the electrical device of the plurality of electrical devices, the future expected progression of the characteristic variable for the electrical device, which is determined according to the method claimed in claim 4, is used as the expected progression of the load factor of the electrical device.

11. A method for managing an operation of the electrical device, in which the electrical load factor of the electrical device at the determination time is adjusted taking into account the characteristic variable determined for the determination time according to the method claimed in claim 1.

12. A system for determining the characteristic variable for representing the thermal load on the electrical device for the determination time, wherein the system comprises a data processor configured to carry out the method as claimed in claim 1.

13. A system for calculating grid safety in the electrical grid comprising the plurality of electrical devices, wherein the system comprises a data processor configured to carry out the method as claimed in claim 10.

14. A system for managing the operation of the electrical device, wherein the system comprises a data processor configured to carry out the method as claimed in claim 11.
